(19) United States
(12) Patent Application Publication
(10) Pub. No.: US 2010/0187539 A1
(43) Pub. Date: Jul. 29, 2010

(54) COMPOUND SEMICONDUCTOR EPITAXIAL WAFER AND FABRICATION METHOD THEREOF

(76) Inventor: Chien-Feng Lin, Hsinchu City (TW)

Correspondence Address: Muncy, Geissler, Olds & Lowe, PLLC, 4000 Legato Road, Suite 310, FAIRFAX, VA, 22033, US

(21) Appl. No.: 12/358,595

(22) Filed: Jan. 23, 2009

(51) Int. Cl. H01L 29/12; H01L 21/20

(52) U.S. Cl. 257/75; 438/483; 257/E21.09; 257/E29.068

(57) ABSTRACT

The present invention provides a compound semiconductor epitaxial wafer and a fabrication method thereof, a first silicon buffer layer is deposited on a metal substrate, and then a second compound semiconductor buffer layer is deposited on the first silicon buffer layer, and a third compound semiconductor buffer layer is deposited on the second compound semiconductor buffer layer, and a first compound semiconductor epitaxial layer is crystallized on the third compound semiconductor buffer layer, and a first thermal treatment process is applied, and a second compound semiconductor epitaxial layer is crystallized on the first compound semiconductor epitaxial layer, and a second thermal treatment process is applied to obtain a good-quality compound semiconductor epitaxial wafer.

### FIELD OF THE INVENTION

The present invention relates to a compound semiconductor and a fabrication method thereof, and more particularly to a compound semiconductor epitaxial wafer grown on a metal substrate and a fabrication method thereof.

### BACKGROUND OF THE INVENTION

As optoelectronic and communication industries advance rapidly, compound semiconductors of Groups III˜V compounds such as, GaAs become a major substrate for manufacturing optoelectronic and communication components due to its advantages of having a direct band-gap and a high carrier mobility and providing a material with different band-gaps obtained by a chemical reaction of different Group III˜V compounds.

The optoelectronic and communication components made of the Group III˜V compound semiconductors mainly use Group III˜V compounds such as, gallium arsenide (GaAs), gallium phosphide (GaP) and indium phosphide (InP) as a substrate for an epitaxial growth under the matched lattice condition. At present, the Group III˜V compound semiconductor substrate is preferably a GaAs or germanium (Ge) substrate with a diameter less than four inches or a mono-crystalline silicon (Si) substrate.

Since there are technical issues of unmatched lattices and different thermal expansion coefficients existed between the buffer layer and the Group III˜V compound semiconductor such as, a silicon buffer layer and a GaAs material have a 4.1% difference of the lattice constant at 25° C. Furthermore, the difference of thermal expansion coefficients between the silicon buffer layer and the GaAs material at 25° C. is approximately equal to 62%. Therefore, the Group III˜V compound semiconductor epitaxial wafer on the buffer layer usually forms a threading dislocation in the compound semiconductor epitaxial layer due to the unmatched lattices and the different thermal expansion coefficients, and gives rise to a poor quality of crystals.

Obviously, the fabrication process, the epitaxial wafer structure and the thermal cycle of annealing heat treatment process in a compound semiconductor epitaxial wafer are the important factors to the quality of the epitaxial wafer.

### SUMMARY OF THE INVENTION

Therefore, it is a primary objective of the present invention to provide a high-quality compound semiconductor epitaxial wafer and a fabrication method thereof, wherein an improved metal substrate is used, and an improved processes for the epitaxial wafer structure and the thermal cycle of annealing heat treatment process are adopted to achieve the effects of improving the quality of crystals, simplifying the process, and lowering the cost.

To achieve the foregoing objective, the present invention provides a fabrication method of a compound semiconductor epitaxial wafer, and the method comprises the steps of: depositing a silicon thin film on a metal substrate to form a first silicon buffer layer; depositing a compound semiconductor thin film on the first silicon buffer layer to form a second compound semiconductor buffer layer; depositing a compound semiconductor thin film on the second compound semiconductor buffer layer to form a third compound semiconductor buffer layer; crystallizing a compound semiconductor thin film on the third compound semiconductor buffer layer to form a first compound semiconductor epitaxial layer; applying a first thermal treatment process; crystallizing a compound semiconductor thin film on the first compound semiconductor epitaxial layer to form a second compound semiconductor epitaxial layer; and applying a second thermal treatment process to complete fabricating the compound semiconductor epitaxial wafer.

To achieve the foregoing objective, the present invention provides a compound semiconductor epitaxial wafer comprising: a metal substrate; a first silicon buffer layer, disposed on the metal substrate; a second compound semiconductor buffer layer, disposed on the first silicon buffer layer; a third compound semiconductor buffer layer, disposed on the second compound semiconductor buffer layer, and processed by a first thermal treatment process; a first compound semiconductor epitaxial layer, disposed on the third compound semiconductor buffer layer; and a second compound semiconductor epitaxial layer, disposed on the first compound semiconductor epitaxial layer, and processed by a second thermal treatment process.

In a preferred embodiment of the present invention, the second compound semiconductor buffer layer, the third compound semiconductor buffer layer, the first compound semiconductor epitaxial layer and the second compound semiconductor epitaxial layer are made of a two-element Group III˜V compound semiconductor material such as GaAs, AlAs, GaP, InAs, and InP, or a three-element or four-element material consisting of the two-element material.

In a preferred embodiment of the present invention, the deposition process is a metal-organic chemical vapor deposition process, and the epitaxial process is a molecular beam epitaxial process. The deposition process of the first silicon buffer layer is conducted at a temperature approximately equal to 580° C.˜600° C., and the deposition thickness is approximately equal to 15 Å˜25 Å. The deposition process of the second compound semiconductor buffer layer is conducted at a temperature approximately equal to 380° C.˜400° C. and the deposition thickness is approximately equal to 10 μm˜20 μm. The deposition process of the third compound semiconductor buffer layer is conducted at a temperature approximately equal to 400° C.˜450° C., and the deposition thickness is approximately equal to 50 Å200 Å. The epitaxial process of the first compound semiconductor epitaxial layer is conducted at a temperature approximately equal to 650° C., and the epitaxial thickness is approximately equal to 1.5 μm˜2 μm. The epitaxial process of the second compound semiconductor epitaxial layer is conducted at a temperature approximately equal to 710° C., and the epitaxial thickness is approximately equal to 1.5 μm∞2 μm.

In a preferred embodiment of the present invention, the first thermal treatment process and the second thermal treatment process are high/low temperature thermal cycle annealing heat treatment processes, and the high/low temperature thermal cycle annealing heat treatment processes go through a high/low thermal cycle for 4 to 8 times.

In the present invention, a metal substrate of the Group III˜V compound semiconductor is used to provide the advantages of a flexible size of the substrate, a low cost, a high heat dissipating, a highly bendable feature and a high carrier mobility, and thus the invention can be applied extensively in the areas of large building curtains, electric cars and 3C products, and comes with a cost much lower than the Group III˜V compound semiconductor substrate using a silicon substrate, so as to achieve a high heat dissipation and a low manufacturing cost for components such as light emitting diodes, photodiodes, solar cells, laser diodes or high power transistors, etc.

In the heat treatment process of the invention, the first silicon buffer layer, the second compound semiconductor buffer layer and the third compound semiconductor buffer layer are working together to reduce the probability of the occurrence of threading dislocations, so as to obtain a better-quality compound semiconductor epitaxial wafer.

### BRIEF DESCRIPTION OF THE DRAWINGS

FIG. 1 is a cross-sectional view of a compound semiconductor epitaxial wafer in accordance with a preferred embodiment of the present invention;

FIG. 2 is a schematic view of high/low temperature heating of a thermal cycle annealing heat treatment in accordance with a preferred embodiment of the present invention;

FIG. 3 shows a metamorphic X-ray rocking curve of a compound semiconductor epitaxial wafer in accordance with a preferred embodiment of the present invention;

FIG. 4 is a cross-sectional view of a solar cell epitaxial wafer in accordance with another preferred embodiment of the present invention.

### DESCRIPTION OF THE PREFERRED EMBODIMENT

Other features and advantages of the present invention will become apparent in the following detailed description of the preferred embodiments with reference to the accompanying drawings.

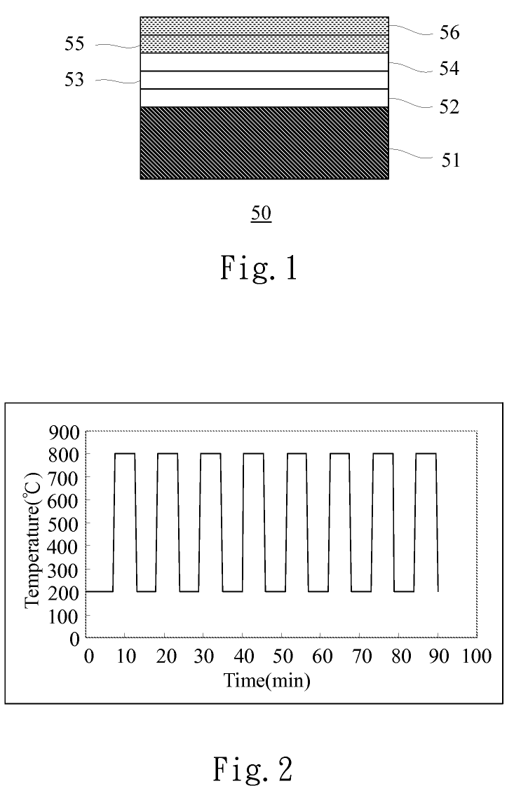

With reference to FIG. 1 for a cross-sectional view of a compound semiconductor epitaxial wafer 50 in accordance with a preferred embodiment of the present invention, a metal-organic chemical vapor deposition process is adopted as the deposition process, and a molecular beam epitaxial process is adopted as an epitaxial process during the crystal growth process, and the compound semiconductor thin film layer is made of gallium arsenide (GaAs). Firstly, a deposition process is conducted on a metal substrate 51 in a crystal growth system, and silane (SiH₄) is used as a reacting gas, and the deposition temperature is approximately equal to 580° C.˜600° C., and a silicon thin film with a thickness approximately equal to 15 Å˜25 Å is deposited on the metal substrate 51, and the silicon thin film can be an amorphous silicon thin film for forming a first silicon buffer layer 52, and then the first silicon buffer layer 52 is went through a deposition process by using reacting gases such as Ga(CH₃)₃ and AsH₃, and a compound semiconductor thin film is deposited at a temperature approximately equal to 380° C.˜400° C. to form a second compound semiconductor buffer layer 53 with a thickness approximately equal to 10 μm to 20 μm, and then a deposition process is performed to the second compound semiconductor buffer layer 53 at a temperature approximately equal to 400° C.˜450° C. by using Ga(CH₃)₃ and AsH₃ as reacting gases to deposit a compound semiconductor thin film to form a third compound semiconductor buffer layer 54 with a thickness approximately equal to 50 Å˜200 Å. An epitaxial process is performed to the third compound semiconductor buffer layer 54 at a temperature approximately equal to 650° C. by using Ga(CH₃)₃ and AsH₃ as reacting gases to crystallize a compound semiconductor thin film to form a first compound semiconductor epitaxial layer 55 with a thickness approximately equal to 1.5 μm˜2 μm. A first thermal cycle annealing heat treatment is conducted in the original crystal growth system.

With reference to FIG. 2 for a schematic view of high/low temperature heating of a thermal cycle annealing heat treatment in accordance with a preferred embodiment of the present invention, the system temperature is lowered to 200° C. and maintained at 200° C. for approximately 7 minutes, and then the system temperature is increased to 800° C. and maintained at 800° C. for approximately 5 minutes. Then the system is lowered to the temperature of 200° C. and maintained at 200° C. for approximately 5 minutes again, and the system temperature is increased to 800° C and maintained at 800° C. for approximately 5 minutes again. The same high/low temperature thermal cycle annealing heat treatment process is repeated for approximately 4 to 8 times to lower the probability of having a threading dislocation occurred between the buffer layer and the first compound semiconductor epitaxial layer 55 due to the lattice constant or the thermal expansion coefficient.

After the first thermal cycle annealing heat treatment is completed, the temperature of the crystal growth system is lowered to approximately 710° C. and then an epitaxial process is performed. In the epitaxial process, Ga(CH₃)₃ and AsH₃ are used as reacting gases for crystallizing a compound semiconductor thin film on the first compound semiconductor epitaxial layer 55 to form a second compound semiconductor epitaxial layer 56 with a thickness approximately equal to 1.5 μm to 2 μm. A second thermal cycle annealing heat treatment is performed in the crystal growth system as shown in FIG. 2. The system temperature is lowered to 200° C. and maintained at 200° C. for approximately 7 minutes, and then the system temperature is increased to 800° C. and maintained at 800° C. for approximately 5 minutes, and the system temperature is lowered to 200° C. and maintained at 200° C. for approximately 7 minutes, and then the system temperature is increased to 800° C. and maintained at 800° C. for approximately 5 minutes again. The same high/low temperature thermal cycle annealing heat treatment process is repeated for 4 to 8 times to reduce the probability of having a threading dislocation occurred at the second compound semiconductor epitaxial layer 56 and eliminating all stress forces between the metal substrate 51 and the second compound semiconductor epitaxial layer 56.

In the foregoing preferred embodiment, the compound semiconductor thin film is made of gallium arsenide (GaAs). Of course, a Group III˜V compound semiconductor two-element material such as aluminum arsenide (AlAs), gallium phosphide (GaP), indium arsenide (InAs), and indium phosphide (InP), or a three-element or four-element material consisting of the two-element can be used for the present invention instead.

The fabrication method of a compound semiconductor epitaxial wafer in accordance with the preferred embodiment of the present invention comprises the steps of: depositing a silicon thin film on a metal substrate 51 to form a first silicon buffer layer 52; depositing a compound semiconductor thin film on the first silicon buffer layer to form a second compound semiconductor buffer layer 53, depositing a compound semiconductor thin film on the second compound semiconductor buffer layer 53 to form a third compound semiconductor buffer layer 54; crystallizing a compound semiconductor thin film at the third compound semiconductor buffer layer 54 to form a first compound semiconductor epitaxial layer 55; applying a first thermal treatment process; crystallizing a compound semiconductor thin film at the first compound semiconductor epitaxial layer 55 to form a second compound semiconductor epitaxial layer 56; and applying a second thermal treatment process, so as to obtain a good-quality compound semiconductor epitaxial wafer 50. In the aforementioned crystal growth process, the deposition process is a metal-organic chemical vapor deposition process, and the epitaxial process is a molecular beam epitaxial process.

A compound semiconductor epitaxial wafer 50 fabricated in accordance with the aforementioned method of the present invention comprises a metal substrate 51, a first silicon buffer layer 52 disposed on the metal substrate 51, a second compound semiconductor buffer layer 53 disposed on the first silicon buffer layer 52, a third compound semiconductor buffer layer 54 disposed on the second compound semiconductor buffer layer 53, a first compound semiconductor epitaxial layer 55 disposed on the third compound semiconductor buffer layer 54, and a second compound semiconductor epitaxial layer 56 disposed on the first compound semiconductor epitaxial layer 55. The first silicon buffer layer 52 and the second compound semiconductor buffer layer 53 are used for combining a threading dislocation in a buffer layer to achieve the effect of lowering the density of threading dislocations, and the third compound semiconductor buffer layer 54 is used for eliminating any threading dislocation remained in the buffer layer. The first compound semiconductor epitaxial layer 54 is used for providing a single crystal structure required for the second compound semiconductor epitaxial layer 55.

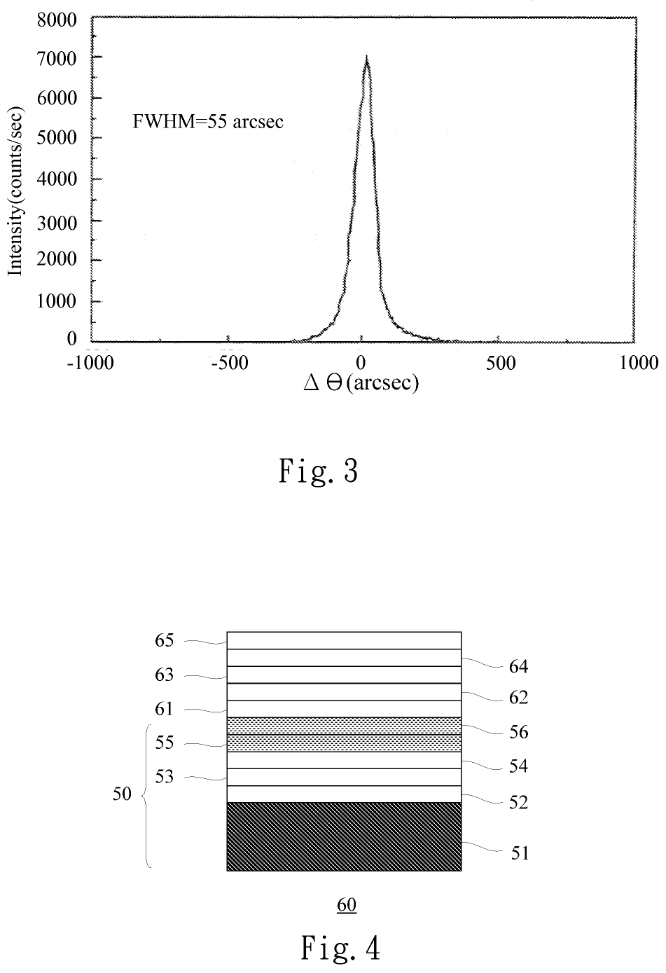

With reference to FIG. 3 for a metamorphic X-ray rocking curve of a compound semiconductor epitaxial wafer 50 in accordance with a preferred embodiment of the present invention, the GaAs compound semiconductor epitaxial layer has a full width at half maximum (FWHM) value of 55 arcsec. The FWHM value of a rocking curve can determine the mosaic structure of the epitaxial wafer's orientation. In other words, when the FWHM value is bigger, the inner orientation of the epitaxial wafer is more irregular, and when the FWHM value is smaller, the inner orientation of the epitaxial wafer is more regular. The compound semiconductor epitaxial wafer grown on the metal substrate of the present invention has the FWHM valve of 55 arcsec. Therefore, from the FWHM value, we can know that the inner orientation of the epitaxial wafer of the present invention is very regular and definitely has better quality.

With reference to FIG. 4 for a cross-sectional view of a solar cell epitaxial wafer 60 in accordance with another preferred embodiment of the present invention, a solar cell epitaxial wafer 60 is fabricated by crystallizing a backside field epitaxial layer 61 on the compound semiconductor epitaxial wafer 50, and then crystallizing a base layer 62, an emitter layer 63, a window layer 64 and a contact layer 65 sequentially to form a solar cell structure.

While the invention has been described by means of specific embodiments, numerous modifications and variations could be made thereto by those skilled in the art without departing from the scope and spirit of the invention set forth in the claims.

What is claimed is:

1. A fabrication method of a compound semiconductor epitaxial wafer, comprising the steps of:
depositing a silicon thin film on a metal substrate to form a first silicon buffer layer;
depositing a compound semiconductor thin film on the first silicon buffer layer to form a second compound semiconductor buffer layer;
depositing a compound semiconductor thin film on the second compound semiconductor buffer layer to form a third compound semiconductor buffer layer;
crystallizing a compound semiconductor thin film on the third compound semiconductor buffer layer to form a first compound semiconductor epitaxial layer;
applying a first thermal treatment process;
crystallizing a compound semiconductor thin film on the first compound semiconductor epitaxial layer to form a second compound semiconductor epitaxial layer; and
applying a second thermal treatment process to complete fabricating a compound semiconductor epitaxial wafer.

2. The fabrication method of claim 1, wherein the compound semiconductor thin films are made of a two-element Group Ill-V compound semiconductor material selected from a collection of gallium arsenide (GaAs), aluminum arsenide (AlAs), gallium phosphide (GaP), indium arsenide (InAs) and indium phosphide (InP), or a three-element material or four-element material consisting of the two-element material.

3. The fabrication method of claim 1, wherein the deposition process is a metal-organic chemical vapor deposition process.

4. The fabrication method of claim 1, wherein the epitaxial process is a molecular beam epitaxial process.

5. The fabrication method of claim 1, wherein the deposition process of the first silicon buffer layer is conducted at a temperature approximately equal to 580° C.˜600° C.

6. The fabrication method of claim 1, wherein the first silicon buffer layer has a thickness approximately equal to 15 Å˜25 Å.

7. The fabrication method of claim 1, wherein the deposition process of the second compound semiconductor buffer layer is conducted at a temperature approximately equal to 380° C.˜400° C.

8. The fabrication method of claim 1, wherein the second compound semiconductor buffer layer has a thickness approximately equal to 10 μm˜20 μm.

9. The fabrication method of claim 1, wherein the deposition process of the third compound semiconductor buffer layer is conducted at a temperature approximately equal to 400° C.˜450° C.

10. The fabrication method of claim 1, wherein the third compound semiconductor buffer layer has a thickness approximately equal to 50 Å˜200 Å.

11. The fabrication method of claim 1, wherein the epitaxial process of the first compound semiconductor epitaxial layer is conducted at a temperature approximately equal to 650° C.

12. The fabrication method of claim 1, wherein the epitaxial process of the second compound semiconductor epitaxial layer is conducted at a temperature approximately equal to 710° C.

13. The fabrication method of claim 1, wherein the first compound semiconductor epitaxial layer has a thickness approximately equal to 1.5 μm˜2 μm.

14. The fabrication method of claim 1, wherein the second compound semiconductor epitaxial layer has a thickness approximately equal to 1.5 μm˜2 μm.

15. The fabrication method of claim 1, wherein the first thermal treatment process and the second thermal treatment process are high/low temperature thermal cycle annealing heat treatment processes, and the high/low temperature thermal cycle annealing heat treatment process goes through a high/low thermal cycle for 4 to 8 times.

16. A compound semiconductor epitaxial wafer, comprising:
a metal substrate;
a first silicon buffer layer, disposed on the metal substrate;
a second compound semiconductor buffer layer, disposed on the first silicon buffer layer;
a third compound semiconductor buffer layer, disposed on the second compound semiconductor buffer layer, and went through a first thermal treatment process;
a first compound semiconductor epitaxial layer, disposed on the third compound semiconductor buffer layer; and
a second compound semiconductor epitaxial layer, disposed on the first compound semiconductor epitaxial layer, and went through a second thermal treatment process.

17. The compound semiconductor epitaxial wafer of claim 16, wherein the second compound semiconductor buffer layer, the third compound semiconductor buffer layer, the first compound semiconductor epitaxial layer and the second compound semiconductor epitaxial layer are made of a two-element Group III-V compound semiconductor material selected from a collection of gallium arsenide (GaAs), aluminum arsenide (AlAs), gallium phosphide (GaP), indium arsenide (InAs) and indium phosphide (InP), or a three-element material or four-element material consisting of the two-element material.

18. The compound semiconductor epitaxial wafer of claim 16, wherein the first silicon buffer layer has a thickness approximately equal to 15 Å25 Å.

19. The compound semiconductor epitaxial wafer of claim 16, wherein the second compound semiconductor buffer layer has a thickness approximately equal to 10 μm˜20 μm.

20. The compound semiconductor epitaxial wafer of claim 16, wherein the third compound semiconductor buffer layer has a thickness approximately equal to 50 Å˜200 Å.

21. The compound semiconductor epitaxial wafer of claim 16, wherein the first compound semiconductor epitaxial layer has a thickness approximately equal to 1.5 μm˜2 μm.

22. The compound semiconductor epitaxial wafer of claim 16, wherein the second compound semiconductor epitaxial layer has a thickness approximately equal to 1.5 μm˜2 μm.

23. The compound semiconductor epitaxial wafer of claim 16, wherein the first thermal treatment process and the second thermal treatment process are high/low temperature thermal cycle annealing heat treatment processes, and the high/low temperature thermal cycle annealing heat treatment process goes through a high/low thermal cycle for 4 to 8 times.
